(19) United States
(12) Patent Application Publication
(10) Pub. No.: US 2025/0337369 A1
(43) Pub. Date: Oct. 30, 2025

(54) CIRCUIT ADJUSTMENT METHOD

(71) Applicant: SMARTER MICROELECTRONICS (GUANG ZHOU) CO., LTD., Guangzhou (CN)

(72) Inventors: Yang HOU, Guangzhou (CN); Jun JIA, Guangzhou (CN)

(73) Assignee: SMARTER MICROELECTRONICS (GUANG ZHOU) CO., LTD., Guangzhou (CN)

(21) Appl. No.: 19/017,649

(22) Filed: Jan. 11, 2025

(30) Foreign Application Priority Data
Apr. 26, 2024 (CN) 202410515341.6

(51) Int. Cl. H03F 1/56

(52) U.S. Cl. CPC H03F 1/56; H03F 2200/294

(57) ABSTRACT

The application relates to the field of electronic technologies. An embodiment of the application provides a circuit adjustment method, the adjustment method includes the following operations. A sampling signal is acquired from an output of an amplifier, the sampling signal includes at least amplitude and/or phase information of a transmission signal and a reflection signal from the output of the amplifier. It is determined whether impedance is mismatched, according to the sampling signal. The impedance is adjusted by an impedance adjustment circuit connected to the output of the amplifier, if the impedance is mismatched.

### CROSS-REFERENCE TO RELATED APPLICATION

The present application claims priority to Chinese Patent Application No. 202410515341.6 filed on Apr. 26, 2024, the disclosure of which is hereby incorporated by reference in its entirety.

### BACKGROUND

In a mobile Radio Frequency (RF) terminal, impedance matching between a Transmit-Receive (TR) module and an antenna greatly affects performance of the terminal, the TR module mainly includes a transmission Power Amplifier (PA) and a receiver Low Noise Amplifier (LNA). In an actual application scenario, impedance of the antenna changes due to environmental effect, which is reflected as poor signal, increased power consumption, or the like in terms of user experience.

### SUMMARY

In view of this, an embodiment of the disclosure provides a circuit adjustment method, the adjustment method includes the following operations. A sampling signal is acquired from an output of an amplifier, the sampling signal includes at least amplitude and/or phase information of a transmission signal and a reflection signal from the output of the amplifier. It is determined whether impedance is mismatched, according to the sampling signal. The impedance is adjusted by an impedance adjustment circuit connected to the output of the amplifier, if the impedance is mismatched.

The disclosure relates to the field of electronic technologies, and in particular to a circuit adjustment method.

In some embodiments, the operation of determining whether impedance is mismatched, according to the sampling signal may include the following operations. A first detection signal containing the amplitude information of the transmission signal and the reflection signal is acquired according to the sampling signal, and it is determined that the impedance is mismatched, when the first detection signal is less than or equal to a first preset threshold. And/or, a second detection signal containing a phase difference between the transmission signal and the reflection signal is acquired according to the sampling signal, and it is determined that the impedance is mismatched, when the second detection signal is greater than a second preset threshold.

In some embodiments, the adjustment method may further include the following operations. The first detection signal is acquired, and the first detection signal is compared with the first preset threshold. And/or, the second detection signal is acquired, and the second detection signal is compared with the second preset threshold.

In some embodiments, the operation of adjusting the impedance by the impedance adjustment circuit connected to the output of the amplifier, if the impedance is mismatched, may include the following operations. The impedance adjustment circuit is controlled to adjust the impedance according to the first detection signal and/or the second detection signal, if the impedance is mismatched.

In some embodiments, the operation of adjusting the impedance by the impedance adjustment circuit connected to the output of the amplifier, if the impedance is mismatched, may include the following operations. The impedance adjustment circuit is controlled to adjust the impedance according to the first detection signal, if the impedance is mismatched. The impedance adjustment circuit is continuously controlled to adjust the impedance according to the second detection signal.

In some embodiments, the adjustment method may further include the following operations before adjusting the impedance by the impedance adjustment circuit connected to the output of the amplifier. The impedance adjustment circuit is reset. It is determined again whether the impedance is mismatched after the impedance adjustment circuit is reset.

In some embodiments, the operation of adjusting the impedance by the impedance adjustment circuit connected to the output of the amplifier, may include the following operations. The impedance is adjusted by looking up a table and/or by traversal.

In some embodiments, the sampling signal may further include frequency information of the transmission signal and the reflection signal from the output of the amplifier.

The operation of adjusting the impedance by the impedance adjustment circuit connected to the output of the amplifier may include the following operations.

The table is looked up according to the amplitude and/or phase information of the transmission signal and the reflection signal in the sampling signal, in combination with the frequency information, and a table lookup result is obtained.

The impedance adjustment circuit is controlled to adjust the impedance, according to the table lookup result.

In some embodiments, the operation of adjusting the impedance by the impedance adjustment circuit connected to the output of the amplifier may include the following operations.

The impedance adjustment circuit is controlled to adjust the impedance, by looking up the table.

The impedance is adjusted by local traversal, if the impedance is still mismatched after the impedance is adjusted.

In some embodiments, the table may include at least a primary table and multiple secondary tables, and the primary table corresponds to multiple secondary tables.

The operation of adjusting the impedance by the impedance adjustment circuit connected to the output of the amplifier may include the following operations.

A table lookup result in the primary table is determined by looking up the table.

The impedance adjustment circuit is controlled to adjust the impedance, according to the table lookup result.

The impedance is adjusted by traversing a secondary table corresponding to the table lookup result, if the impedance is still mismatched after the impedance is adjusted.

In some embodiments, the operation of acquiring the sampling signal from the output of the amplifier may include the following operations.

The sampling signal is acquired from the output of the amplifier at a fixed time.

In some embodiments, a time interval for acquiring the sampling signal at the fixed time may be 50 to 200 ms.

In the circuit adjustment method provided in each embodiment of the disclosure, a state whether the impedance is mismatched, is determined by detecting the sampling signal from the output of the amplifier; in case of mismatch, the impedance is adjusted by the impedance adjustment circuit connected to the output of the amplifier, to achieve impedance matching. In this way, the impedance may be adaptively adjusted according to different situations of the output of the amplifier, to achieve impedance matching in different situations, thereby optimizing matching of output impedance of the amplifier and radiation efficiency of the transmission signal of the amplifier, improving communication quality, and further improving the user experience.

### BRIEF DESCRIPTION OF THE DRAWINGS

FIG. 1 is a schematic composition diagram of partial hardware of a terminal device to which a circuit adjustment method provided in an embodiment of the disclosure is applied.

FIG. 2A is a first implementation flowchart of a circuit adjustment method provided in an embodiment of the disclosure.

FIG. 2B is a second implementation flowchart of a circuit adjustment method provided in an embodiment of the disclosure.

FIG. 3 is an application implementation flowchart of a circuit adjustment method provided in an embodiment of the disclosure.

FIG. 4 is a first example of a circuit to which a circuit adjustment method provided in an embodiment of the disclosure is applied.

FIG. 5 is a second example of a circuit to which a circuit adjustment method provided in an embodiment of the disclosure is applied.

FIG. 6 is a third example of a circuit to which a circuit adjustment method provided in an embodiment of the disclosure is applied.

FIG. 7 is a fourth example of a circuit to which a circuit adjustment method provided in an embodiment of the disclosure is applied.

### DETAILED DESCRIPTION

The disclosure will be further described in detail below with reference to the drawings and embodiments. It should be understood that specific embodiments described below in the disclosure are only intended to explain the disclosure and are not intended to limit the disclosure.

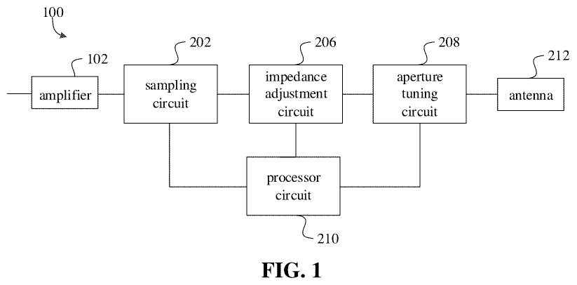

FIG. 1 is a schematic composition diagram of partial hardware of a terminal device to which a circuit adjustment method provided in an embodiment of the disclosure is applied. In some embodiments, with reference to FIG. 1, the terminal device 100 may include an amplifier 102, a sampling circuit 202, a processor circuit 210, an impedance adjustment circuit 206, an aperture tuning circuit 208, and an antenna 212. The sampling circuit 202, the impedance adjustment circuit 206 and the aperture tuning circuit 208 are sequentially connected in series between the amplifier 102 and the antenna 212, and the processor circuit 210 is coupled to the sampling circuit 202, the impedance adjustment circuit 206 and the aperture tuning circuit 208. Here, coupling may be understood as direct connection or indirect connection through other circuits.

In some embodiments, the terminal device 100 may be a portable wireless communication device, such as a laptop or portable computer with wireless communication capabilities, a web tablet computer, a wireless phone, a smart phone, a wireless headset, etc. The amplifier 102 may include a Power Amplifier (PA), and more specifically, may include a transmission PA and/or a receiver Low Noise Amplifier (LNA) which is configured to amplify a received signal and/or a transmitted signal. The sampling circuit 202 may be configured to acquire a signal from an output of the amplifier 102. The processor circuit 210 is configured to control the impedance adjustment circuit 206 and/or the aperture tuning circuit 208 to perform adjustment when mismatch of a path is detected, according to the signal acquired by the sampling circuit 202, thereby reducing a reflection signal from the output of the amplifier.

In some specific embodiments, the impedance adjustment circuit 206 is controlled to adjust impedance, i.e., tune the impedance, to reduce loss caused by impedance mismatch, thereby optimizing power of an output signal of the amplifier 102 transmitted to the antenna 212. In some specific embodiments, the aperture tuning circuit 208 is controlled to perform aperture tuning, i.e., aperture tuning, which may adjust an electrical length of the antenna 212, and switch a resonance point thereof to an operation band which needs to be supported, thereby improving radiation efficiency of the antenna 212. When impedance of the path is mismatched, the impedance may be adjusted by the impedance adjustment circuit 206, or the impedance may be adjusted by the impedance adjustment circuit 206 and the aperture tuning circuit 208 together, so that the mismatched impedance is matched again, thereby achieving dynamic adjustment of the impedance, reducing the reflection signal and improving antenna efficiency. Adjustment of the impedance adjustment circuit 206 and adjustment of the aperture tuning circuit 208 are not divided into primary adjustment and secondary adjustment, and each of the two adjustments may be primary adjustment; or, one of the two adjustments may be primary adjustment, and another one of the two adjustments may be fine adjustment, which is not limited here.

In some embodiments, the terminal device 100 may omit the aperture tuning circuit 208. In some embodiments, the terminal device 100 may omit the antenna 112. In some embodiments, the terminal device 100 may further include an Electro-Static Discharge (ESD) 110. It should be understood that FIG. 1 is only an example of terminal devices to which the provided circuit adjustment method is applied, and is not intended to limit the terminal device to which the circuit adjustment method provided in the embodiment of the disclosure is applied. In other embodiments, corresponding composition circuits may also be added or reduced based on FIG. 1.

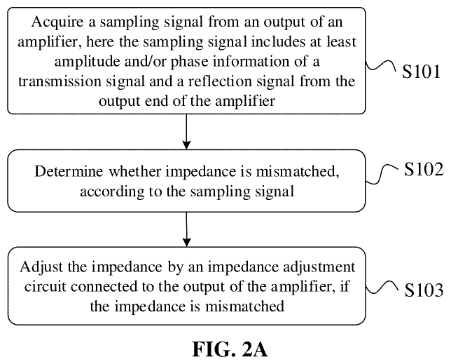

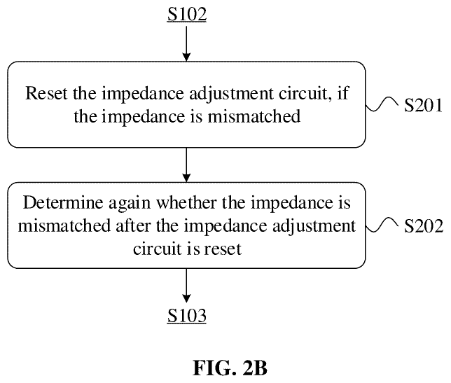

An embodiment of the disclosure provides a circuit adjustment method, with reference to FIG. 2A, the adjustment method includes the following operations S101 to S103. In operation S101, a sampling signal is acquired from an output of an amplifier, the sampling signal includes at least amplitude and/or phase information of a transmission signal and a reflection signal from the output of the amplifier. In operation S102, it is determined whether impedance is mismatched, according to the sampling signal. In operation S103, the impedance is adjusted by an impedance adjustment circuit connected to the output of the amplifier, if the impedance is mismatched.

It should be understood that the operations shown in FIG. 2A are not exclusive, and other operations may be performed before, after or between any of the shown operations. Implementation processes of the circuit adjustment method will be described in detail below with reference to FIG. 1 and FIG. 2A.

It should be noted that an execution body corresponding to each circuit adjustment method in the embodiments of the disclosure may be the foregoing processor circuit 210. In some specific embodiments, the processor circuit 210 may include one or more Micro Controller Units (MCUs), Field Programmable Gate Arrays (FPGAs), Digital Signal Processors (DSPs), Application Specific Integrated Circuits (ASICs), Radio-Frequency Integrated Circuits (RFICs), or the like configured to perform at least functions described here.

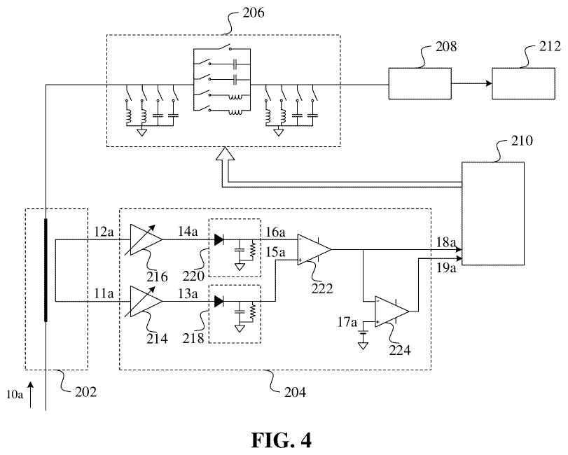

The operation S101 is performed, to mainly acquire the sampling signal. In some embodiments, an output signal from the output of the amplifier (which may be understood as an output signal 10a in FIG. 4 to FIG. 7) may be a Radio Frequency (RF) signal. Exemplarily, the sampling signal may include the amplitude information of the transmission signal and the amplitude information of the reflection signal; the sampling signal may include the phase information of the transmission signal and the phase information of the reflection signal; the sampling signal may further include the amplitude information and phase information of the transmission signal and the amplitude information and phase information of the reflection signal.

In some embodiments, the transmission signal and the reflection signal from the output of the amplifier may be sampled by the sampling circuit 202 connected to the output of the amplifier. In some specific embodiments, the sampling circuit 202 may include a coupler, the coupler is connected to the output of the amplifier 102 and samples the transmission signal and the reflection signal from the output of the amplifier 102. A number of couplers may be selected according to requirements, and the two signals may be acquired by one coupler or two couplers. It should be noted that sampling parameters of the couplers may be the same or different, which is not limited here. For example, a coupling degree of the transmission signal may be the same as or different from that of the reflection signal. For another example, the coupling degree of the reflection signal is greater than that of the transmission signal. In some embodiments, manners for the sampling circuit 202 to acquire the sampling signal from the output of the amplifier may be acquiring in real time/at a fixed time.

In some specific embodiments, the operation of acquiring the sampling signal from the output of the amplifier includes the following operations. The sampling signal is acquired from the output of the amplifier at a fixed time. In this way, it is unnecessary for the sampling circuit to be in a state of acquiring the sampling signal all the time.

In some specific embodiments, a time interval for acquiring the sampling signal at the fixed time is 50 to 200 ms. Exemplarily, the time interval for acquiring the sampling signal at the fixed time may be 50 ms, 100 ms, 150 ms, or 200 ms.

The operation S102 is performed, to mainly determine whether output impedance at the output of the amplifier is mismatched, according to the acquired sampling signal.

In some embodiments, the operation of determining whether impedance is mismatched, according to the sampling signal includes the following operations. A first detection signal containing the amplitude information of the transmission signal and the reflection signal is acquired according to the sampling signal, and it is determined that the impedance is mismatched, when the first detection signal is less than or equal to a first preset threshold. And/or, a second detection signal containing a phase difference between the transmission signal and the reflection signal is acquired according to the sampling signal, and it is determined that the impedance is mismatched, when the second detection signal is greater than a second preset threshold.

It should be noted that results of comparing the first detection signal and the second detection signal with respective preset thresholds are intended to determine whether the impedance is mismatched, and a basis for determination is set according to relevant structures. That is, it may also be determined that the impedance is mismatched, when the first detection value is greater than the first preset threshold, which is not limited in the disclosure.

In some specific embodiments, the first preset threshold may be set according to a Voltage Standing Wave Ratio (VSWR). There may be one or more preset thresholds, so as to be selected according to different situations.

In some embodiments, the processor circuit 210 may acquire the first detection signal and a first comparison result through a first detector circuit connected to an output of the sampling circuit 202. The first detector circuit compares amplitude of the sampled transmission signal with amplitude of the sampled reflection signal, and outputs the first detection signal containing the amplitude information of the transmission signal and the reflection signal; and compares the first detection signal with the first preset threshold, and outputs the first comparison result. The processor circuit may determine whether the impedance is mismatched, according to states of the first comparison result. When the first comparison result is in a first state, it indicates that the first detection signal is less than or equal to the first preset threshold, which determines that the impedance is mismatched. When the first comparison result is in a second state, it indicates that the first detection signal is greater than the first preset threshold, which determines that the impedance is not mismatched.

Here, the amplitude information may include amplitude ratio information, or amplitude difference information, etc. Specific situations of the amplitude information may be set according to structures of comparators, that is, different comparators may calculate a difference between the input transmission signal and the input reflection signal or calculate a ratio of the input transmission signal to the input reflection signal according to different internal structures, and output corresponding difference or ratio information.

It should be noted that there is a difference between two inputs of the comparator. Inputting the transmission signal and the reflection signal to inputs of the comparator exchangeably may result in exchange of numerator and denominator of the amplitude ratio information or exchange of subtrahend and minuend of the amplitude difference information. Therefore, input situations of the two signals need to be considered when the first detection signal is compared with the first preset threshold, thereby determining specific conditions for determining whether the impedance is mismatched, according to actual situations.

In some specific embodiments, with reference to FIG. 4, the first detector circuit 204 includes a first amplifier 214, a first detection circuit 218, and/or a second amplifier 216, a second detection circuit 220, a first comparator 222 and a second comparator 224. The first amplifier 214 is coupled to the output of the sampling circuit 202, receives a sampled transmission signal 11a, amplifies the sampled transmission signal 11a, and is provided with an output outputting a first amplification signal 13a. The first detection circuit 218 is coupled to an output of the first amplifier 214, is configured to rectify the first amplification signal 13a, and is provided with an output coupled to a first end of the first comparator 222 and outputting a first rectification signal 15a. The second amplifier 216 is coupled to the output of the sampling circuit 202, receives a sampled reflection signal 12a, amplifies the sampled reflection signal 12a, and is provided with an output outputting a second amplification signal 14a. The second detection circuit 220 is provided with an input coupled to the output of the sampling circuit 202 and receiving the sampled reflection signal 12a, and is configured to detect the sampled reflection signal 12a, and is provided with an output coupled to a second end of the first comparator 222 and outputting a second rectification signal 16a. The first comparator 222 is configured to compare amplitude of the first rectification signal 15a corresponding to the sampled transmission signal 11a with amplitude of the second rectification signal 16a corresponding to the sampled reflection signal 12a, and output a first detection signal 18a. The second comparator 224 is provided with a second end connected to an output of the first comparator 222 and receiving the first detection signal 18a, and a first end receiving a first reference signal 17a (it is configured to indicate the first preset threshold), the second comparator 224 is configured to compare the first reference signal 17a with the first detection signal 18a and output a first comparison result 19a.

The first comparison result 19a is transmitted to the processor circuit 210. The first comparison result 19a is configured to turn on or off adjustment of the impedance performed by the impedance adjustment circuit. At this time, adjustment of the impedance performed by the impedance adjustment circuit is turned on or off by the first comparison result, the first detection signal is received, and the impedance is adjusted according to the first detection signal. In this way, adjustment of the impedance performed by the impedance adjustment circuit is turned on or off by the first comparison result, so that signal processing may be simplified, and it is unnecessary to process the first detection signal when it is unnecessary to adjust the impedance.

In some specific embodiments, the first amplifier 214 and the second amplifier 216 in FIG. 4 and/or the first detection circuit 218 and the second detection circuit 220 in FIG. 4 may be omitted. It should be noted that after corresponding circuits are omitted, signals transmitted to both ends of the first comparator 222 need to be adjusted correspondingly.

In some other embodiments, the processor circuit 210 may acquire the first detection signal through the first detector circuit connected to the output of the sampling circuit 202, and directly compare the first detection signal with the first preset threshold inside the processor circuit 210, to obtain the first comparison result. Then, it is also determined whether the impedance is mismatched according to states of the first comparison result.

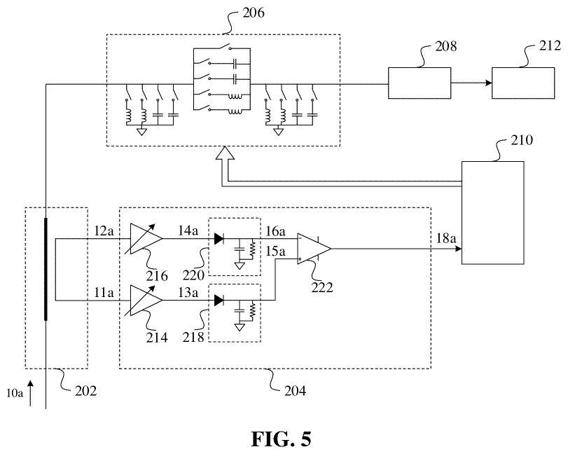

In some specific embodiments, with reference to FIG. 5, where the second comparator 224 is omitted based on FIG. 4, and the first detection signal obtained by the first comparator 222 is directly transmitted to the processor circuit 210. In some specific embodiments, the first amplifier 214 and the second amplifier 216 in FIG. 4, and/or the first detection circuit 218 and the second detection circuit 220 in FIG. 4 may also be omitted in FIG. 5.

In some embodiments, the second preset threshold may be set according to VSWR. There may be one or more second preset thresholds, so as to be selected according to different situations.

In some embodiments, the processor circuit 210 may acquire the second detection signal and a second comparison result through a second detector circuit connected to the output of the sampling circuit 202. The second detector circuit compares phase of the sampled transmission signal with phase of the sampled reflection signal, and outputs the second detection signal containing the phase difference between the transmission signal and the reflection signal; and compares the second detection signal with the second preset threshold, and outputs the second comparison result. The processor circuit may determine whether the impedance is mismatched, according to states of the second comparison result. When the second comparison result is in a first state, it indicates that the second detection signal is greater than the second preset threshold, which determines that the impedance is mismatched. When the second comparison result is in a second state, it indicates that the second detection signal is less than or equal to the second preset threshold, which determines that the impedance is not mismatched.

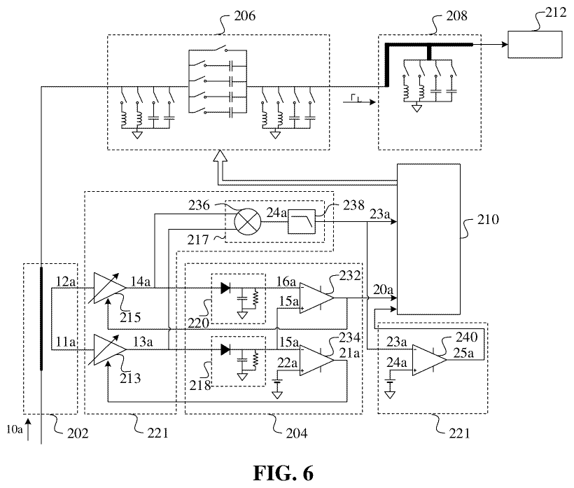

In some specific embodiments, with reference to FIG. 6, the second detector circuit 221 includes a third amplifier 213, and/or a fourth amplifier 215, a mixing circuit 217, a first detection circuit 218, a second detection circuit 220, a third comparator 232, a fourth comparator 234, and a fifth comparator 240. The third amplifier 213 receives a sampled transmission signal 11a, adjusts amplitude of the sampled transmission signal 11a, and outputs a first amplification signal 13a. The fourth amplifier 215 receives a sampled reflection signal 12a, adjusts amplitude of the sampled reflection signal 12a, and outputs a second amplification signal 14a. The mixing circuit 217 (it includes a mixer 236 and a filter 238) receives the first amplification signal 13a and the second amplification signal 14a, and performs mixing, to output a second detection signal 23a. The first detection circuit 218 is configured to rectify the first amplification signal and output a first rectification signal 15a. The second detection circuit 220 is configured to rectify the second amplification signal and output a second rectification signal 16a. The third comparator 232 receives the first rectification signal 15a and the second rectification signal 16a, outputs a third comparison result 20a, is provided with an output connected to the fourth amplifier 215, and is configured to adjust amplitude of the second amplification signal 14a. The fourth comparator 234 receives a second reference signal 22a and the first rectification signal 15a, outputs a fourth comparison result 21a, is provided with an output connected to the third amplifier 213, and is configured to adjust amplitude of the first amplification signal 13a. The fifth comparator 240 compares a third reference signal 24a (it is configured to indicate the second preset threshold) with the second detection signal 23a, outputs a second comparison result, and is provided with an output connected to the processor circuit 210.

In some embodiments, when the third amplifier 213 forms a feedback loop with the fourth comparator 234 and the fourth amplifier 215 forms a feedback loop with the third comparator 232, after each of the third comparator 232 and the fourth comparator 234 is stable, each of the second amplification signal 14a and the first amplification signal 13a is the same as the second reference signal 22a, so that the amplitude of the second amplification signal 14a is the same as that of the first amplification signal 13a, and the two signals are input to the mixing circuit 217. The mixing circuit 217 receives signals with equal amplitude. The second detection signal 23a output by the mixing circuit 217 and a second comparison result 25a output by the fifth comparator 240 are transmitted to the processor circuit 210.

In some specific embodiments, the third amplifier 213 and the fourth amplifier 215 in FIG. 6 and/or the first detection circuit 218 and the second detection circuit 220 in FIG. 6 may be omitted. It should be noted that after corresponding circuits are omitted, signals transmitted to both ends of the mixing circuit 217 and both ends of the fifth comparator 240 need to be adjusted correspondingly.

In some other embodiments, the processor circuit 210 may acquire the second detection signal through the second detector circuit connected to the output of the sampling circuit 202, and directly compare the second detection signal with the second preset threshold inside the processor circuit 210, to obtain the second comparison result. Then, it is also determined whether the impedance is mismatched according to states of the second comparison result.

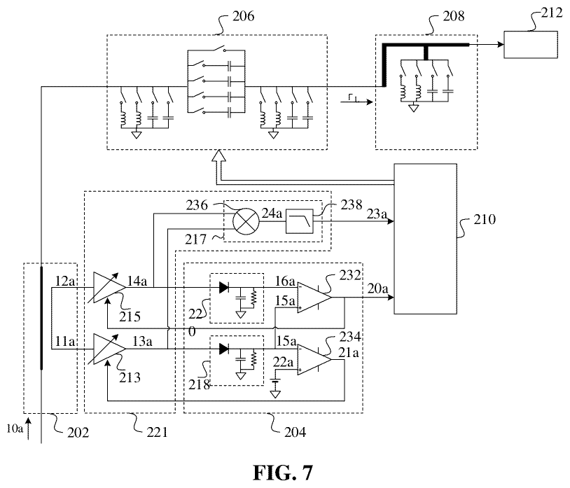

In some specific embodiments, with reference to FIG. 7, where the fifth comparator 240 is omitted based on FIG. 6, and the second detection signal 23a obtained by the mixing circuit 217 is directly transmitted to the processor circuit 210. In some specific embodiments, the third amplifier 213 and the fourth amplifier 215 in FIG. 7, and/or the first detection circuit 218 and the second detection circuit 220 in FIG. 7, and/or the third comparator 232 and the fourth comparator 234 in FIG. 7 may also be omitted.

It should be noted that a turn-on comparator (i.e., the second comparator 224) is omitted in FIG. 5 compared to FIG. 4. At this time, the first preset value is set in the processor circuit 210, and when value of a sampling comparator (i.e., the first comparator 222) is less than the first preset value, the impedance adjustment circuit is turned on. A turn-on comparator (i.e., the fifth comparator 240) is omitted in FIG. 7 compared to FIG. 6. At this time, the second preset value is set in the processor circuit 210, and when the second detection signal 23a obtained by the mixing circuit 217 is greater than the second preset value, the impedance adjustment circuit is turned on. In some embodiments, when the impedance adjustment circuit is turned on, it is unnecessary for the processor circuit 210 to be in a state of receiving all the time, which may reduce a data processing amount of the processor circuit 210.

In some embodiments, circuits in FIG. 4 to FIG. 7 may be combined to obtain the first detection signal and the second detection signal simultaneously.

In some embodiments, after the processor circuit 210 acquires the sampling signal through the sampling circuit 202, the processor circuit 210 may directly perform operations (such as difference operation and comparison operation) on the amplitude and/or phase information of the transmission signal and the reflection signal inside the processor circuit 210, so that the first detection signal and/or the second detection signal, the first comparison result between the first detection signal and the first preset threshold, and/or the second comparison result between the second detection signal and the second preset threshold are directly obtained, thereby determining whether the impedance fails. In this way, area of a signal processing circuit may be saved, which is beneficial for integration.

Here, determination of whether the output impedance fails, completes.

In some embodiments, with reference to FIG. 2B, the following operations S201 and S202 may also be performed before the operation S103 is performed. In operation S201, the impedance adjustment circuit is reset. In operation S202, it is determined again whether the impedance is mismatched after the impedance adjustment circuit is reset.

When the operation S201 is performed and it is determined that the impedance is mismatched, the impedance adjustment circuit may be controlled to be reset by the processor circuit 210. In some specific embodiments, the impedance adjustment circuit may be controlled to be reset by sending a reset command, etc. In this way, when influence of external environment disappears, adjustment may be performed quickly.

The operation S201 is performed, after the impedance adjustment circuit is reset, the sampling signal of the path is acquired again, and it is determined whether the impedance is mismatched. Manners of determining whether the impedance is mismatched may be similarly understood with reference to the foregoing operation S102, which is not elaborated here.

The operation S103 is performed after the operation S102 or S202, to control the impedance adjustment circuit to adjust the impedance when mismatch occurs, so that impedance matching returns to normal. In some embodiments, the processor circuit 210 may also control the impedance adjustment circuit and the aperture tuning circuit to perform adjustment, so that the impedance matching returns to normal.

In some embodiments, the operation of adjusting the impedance by the impedance adjustment circuit if the impedance is mismatched, includes the following operations. The impedance adjustment circuit is controlled to adjust the impedance according to the first detection signal and/or the second detection signal, if the impedance is mismatched.

In some specific embodiments, after the impedance adjustment circuit is turned on in response to mismatch, adjustment degree of the impedance adjustment circuit may be controlled according to a specific size of the amplitude information of the transmission signal and the reflection signal reflected by the first detection signal. Exemplarily, the smaller the amplitude information of the transmission signal and the reflection signal, the more serious the impedance mismatch situation, and at this time, there are more impedance space which needs to be adjusted by controlling the impedance adjustment circuit.

In some specific embodiments, after the impedance adjustment circuit is turned on in response to mismatch, adjustment degree of the impedance adjustment circuit may be controlled according to a specific size of the phase difference between the transmission signal and the reflection signal reflected by the second detection signal. Exemplarily, the larger the phase difference between the transmission signal and the reflection signal, the more serious the impedance mismatch situation, and at this time, there are more impedance space which needs to be adjusted by controlling the impedance adjustment circuit.

In some specific embodiments, after the impedance adjustment circuit is turned on in response to mismatch, adjustment degree of the impedance adjustment circuit may also be controlled according to the specific size of the amplitude information reflected by the first detection signal and the specific size of the phase difference reflected by the second detection signal. Specifically, the impedance adjustment circuit is controlled to adjust the impedance according to the first detection signal, and the impedance adjustment circuit is continued to be controlled to adjust the impedance according to the second detection signal. That is, the impedance adjustment circuit may be controlled to adjust the impedance according to the first detection signal first, and then when impedance mismatch is reduced to a certain extent or even when the impedance is not mismatched, the impedance adjustment circuit may be continued to be controlled to adjust the impedance according to the second detection signal, to achieve a better impedance matching state. The impedance may also be adjusted according to the first detection signal and the second detection signal simultaneously; or, the impedance may be adjusted according to the second detection signal first, and then the impedance may be adjusted according to the first detection signal. In some specific embodiments, the first preset value and/or the second preset value may be set to multiple values respectively, to indicate impedance matching situations of different states.

In some specific embodiments, when a controller circuit controls the impedance adjustment circuit to perform adjustment according to the first detection signal and/or the second detection signal, the controller circuit relies on the first detection signal and/or the second detection signal acquired in real time or at a fixed time, so that impedance adjustment degree of the impedance adjustment circuit may be flexibly adjusted according to variation of the first detection signal and/or the second detection signal, to facilitate the impedance restoring the matching state quickly. When the first comparison result/the second comparison result corresponding to the first detection signal and/or the second detection signal acquired in real time or at the fixed time is in a non-mismatch range, the impedance adjustment circuit is controlled to close adjustment.

In some embodiments, the operation of adjusting the impedance by the impedance adjustment circuit if the impedance is mismatched, includes the following operations. The impedance is adjusted by looking up a table and/or by traversal, if the impedance is mismatched.

In some embodiments, if the impedance is mismatched, impedance value to be adjusted by the impedance adjustment circuit may be determined by looking up the table according to the first detection signal and/or the second detection signal. Here, the table stores a mapping relationship between the first detection signal and/or the second detection signal and the to-be-adjusted impedance value. The number of times for adjusting the impedance by looking up the table may include one or many times.

In some specific embodiments, the sampling signal further includes frequency information of the transmission signal and the reflection signal from the output of the amplifier. The operation of adjusting the impedance by the impedance adjustment circuit includes the following operations. The table is looked up according to the amplitude and/or phase information of the transmission signal and the reflection signal in the sampling signal, in combination with the frequency information, and a table lookup result is obtained. The impedance adjustment circuit is controlled to adjust the impedance, according to the table lookup result.

In some embodiments, different tables may be set according to different frequencies, and different tables store different mapping relationships between the first detection signal and/or the second detection signal and the to-be-adjusted impedance value. Exemplarily, the band is divided into high/medium/low frequencies, and to-be-adjusted impedance values corresponding to the same first detection signal and/or second detection signal in different bands are different. In this way, when used bands are switched, the impedance may also be adjusted by the adjustment circuit, to make it applicable to different bands. In some embodiments, the processor circuit includes a memory circuit, the memory circuit is configured to store a table (such as a Look-Up-Table (LUT)). In some embodiments, the memory circuit may be a Random Access Memory (RAM). It should be noted that the mapping relationship of the detection signal may also be provided in different tables. For example, mapping relationships of the first detection signal and the second detection signal are provided in different tables respectively; for another example, when the impedance is adjusted according to the first detection signal and the second detection signal, the mapping relationship in the table is an impedance adjustment mode corresponding to deviation between the first detection signal and the second detection signal, rather than an impedance adjustment mode corresponding to one of the two signals.

In some embodiments, the impedance may be adjusted by traversal, if the impedance is mismatched. Specifically, after the impedance adjustment circuit is turned on in response to mismatch, the impedance adjustment circuit performs at least one adjustment according to a combination of preset to-be-adjusted impedance values, and determines whether the impedance is mismatched after each adjustment, until the first comparison result/the second comparison result is in the non-mismatch range, and the impedance adjustment circuit stops adjustment. In some embodiments, the table lookup and traversal may be performed simultaneously or separately; and the two adjustments may perform primary adjustment on the impedance, or may perform fine adjustment on the impedance, or the fine adjustment may not be required. For example, the primary adjustment is performed by traversal, and then the fine adjustment is performed by looking up the table; for another example, the primary adjustment is performed by looking up the table, and then the fine adjustment is performed by traversal; for another example, the primary adjustment and the fine adjustment are performed by traversal or by looking up the table; for another example, the adjustment is performed by traversal or by looking up the table.

In some specific embodiments, the operation of adjusting the impedance by the impedance adjustment circuit includes the following operations. The impedance adjustment circuit is controlled to adjust the impedance, by looking up the table. The impedance is adjusted by local traversal, if the impedance is still mismatched after the impedance is adjusted.

Here, the primary adjustment may be performed by looking up the table, and then the fine adjustment may be performed by traversal. It may also be understood as roughly adjusting the impedance by looking up the table, and finely adjusting the impedance by local traversal.

In some embodiments, the table includes at least a primary table and multiple secondary tables, and the primary table corresponds to multiple secondary tables. The operation of adjusting the impedance by the impedance adjustment circuit includes the following operations. A table lookup result in the primary table is determined by looking up the table. The impedance adjustment circuit is controlled to adjust the impedance, according to the table lookup result. It is determined whether the impedance is mismatched, after adjustment is performed according to the table lookup result. The impedance is adjusted by traversing a secondary table corresponding to the table lookup result, if the impedance is still mismatched after the impedance is adjusted according to the table lookup result.

That is, the impedance may be adjusted by looking up the primary table. If the impedance is still mismatched after the impedance adjustment circuit performs adjustment according to a result of looking up the primary table, the impedance adjustment circuit may adjust the impedance by traversing the secondary table corresponding to the result of looking up the primary table. In this way, over-adjustment is not easy to occur, so that the impedance may be adjusted to be in an impedance matching range more quickly.

It should be noted that in other embodiments, the impedance may be adjusted by looking up the primary table or by traversing the primary table. Similar principles are applicable to the secondary table, which is not elaborated here. For example, with respect to the primary table and the secondary table, the impedance is adjusted by looking up the table.

In some embodiments, the table may further include a multi-level table, such as a three-level table, a four-level table, etc. Adjustment thereof may refer to the above embodiments and is not elaborated here.

In some embodiments, the impedance adjustment circuit 206 and the aperture tuning circuit 208 may be integrated into the same module. In this way, requirements of important indices such as low cost, miniaturization or the like of the adjustment circuit may be met. In other embodiments, the impedance adjustment circuit 206 and the aperture tuning circuit 208 may also be located in different modules respectively.

In some embodiments, the impedance adjustment circuit 206 includes a first branch, a second branch, and a third branch. The first branch is provided with a first end connected to the sampling circuit, and a second end which is grounded. The second branch is provided with a first end connected to the aperture tuning circuit, and a second end which is grounded. The third branch is provided with a first end and a second end connected to the first end of the first branch and the first end of the second branch respectively.

In some embodiments, the impedance adjustment circuit 206 includes one or more π-type three-element impedance matching circuits. In some specific embodiments, a π-type three-element impedance matching circuit may be formed of one inductor and two capacitors, or, of one capacitor and two inductors. In some specific embodiments, the inductor in an impedance matching circuit may be set as an adjustable inductor, and/or, the capacitor in an impedance matching circuit may be set as an adjustable capacitor, to enable the impedance matching circuit to adjust impedance conversion according to different RF signals. For example, impedance conversion adjustment may be performed on signals in different bands.

In some embodiments, at least one of the first branch, the second branch, or the third branch is provided with multiple inductors and/or capacitors connected in parallel, and a switch is connected in series with at least one path of the parallel circuit. In some specific embodiments, the inductor in the impedance matching circuit 206 may be set as an adjustable inductor, and/or, the capacitor in the impedance matching circuit 206 may be set as an adjustable capacitor, to enable the impedance matching circuit 260 to adjust impedance conversion according to different RF signals. For example, impedance conversion adjustment may be performed on signals in different bands.

In the embodiments of the disclosure, a state whether the impedance is mismatched, is determined by detecting the sampling signal from the output of the amplifier; in case of mismatch, the impedance is adjusted by the impedance adjustment circuit connected to the output of the amplifier, to achieve impedance matching. In this way, the impedance may be adaptively adjusted according to different situations of the output of the amplifier, to achieve impedance matching in different situations, thereby optimizing matching of output impedance of the amplifier and radiation efficiency of the transmission signal of the amplifier, improving communication quality, and further improving the user experience.

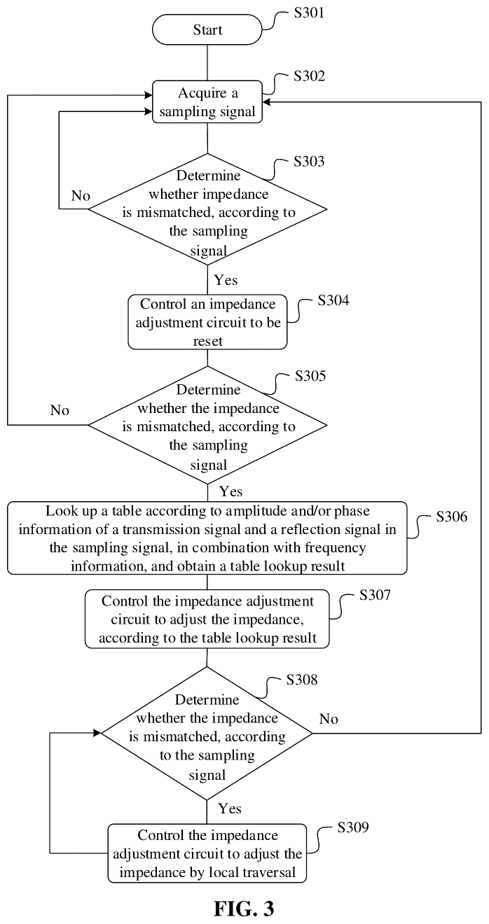

FIG. 3 is an application implementation flowchart of a circuit adjustment method provided in an embodiment of the disclosure. The circuit adjustment method provided in the embodiment of the disclosure will be described in detail below with reference to FIG. 3.

With reference to FIG. 3, exemplarily, the operation S301 may be performed by the processor circuit to start the flow, and at this time, it starts to perform the circuit adjustment method.

The operation S302 is performed to acquire a sampling signal, the sampling signal includes at least amplitude and/or phase information of a transmission signal and a reflection signal from an output of an amplifier.

After the operation S302 is performed each time, the operation S303 is performed, to acquire a first detection signal containing the amplitude information of the transmission signal and the reflection signal, according to the sampling signal; and determine whether impedance is mismatched, according to whether the first detection signal is less than or equal to a first preset threshold; and/or, acquire a second detection signal containing a phase difference between the transmission signal and the reflection signal, according to the sampling signal; and determine whether the impedance is mismatched, according to whether the second detection signal is greater than a second preset threshold.

If the first detection signal is less than or equal to the first preset threshold and/or the second detection signal is greater than the second preset threshold, it is determined that the impedance is mismatched; otherwise, it is determined that the impedance is not mismatched. After determining that the impedance is mismatched, the operation S304 is performed; and after determining that the impedance is not mismatched, the operation S302 and operations after the operation S302 are performed again.

The operation S304 is performed, to control an impedance adjustment circuit to be reset.

After the operation S304 is performed, the sampling signal is acquired again, and the operation S305 is performed, to determine whether the impedance is mismatched according to the first detection signal and/or the second detection signal corresponding to the sampling signal, after the impedance adjustment circuit is reset. Specific determination may refer to the operation S303, which is not elaborated here. After determining that the impedance is mismatched, the operation S306 is performed; and after determining that the impedance is not mismatched, the operation S302 and operations after the operation S302 are performed again.

The operation S306 is performed, to look up a table according to amplitude and/or phase information of a transmission signal and a reflection signal in the sampling signal, in combination with frequency information, and obtain a table lookup result.

After the operation S306 is performed, the operation S307 is performed, to control the impedance adjustment circuit to adjust the impedance, according to the table lookup result.

After the operation S307 is performed, the sampling signal is acquired again, and the operation S308 is performed, to determine whether the impedance is mismatched according to the first detection signal and/or the second detection signal corresponding to the sampling signal after the impedance is adjusted based on the table lookup result. Specific determination may refer to the operation S303, which is not elaborated here. After determining that the impedance is mismatched, the operation S309 is performed; and after determining that the impedance is not mismatched, the operation S302 and operations after the operation S302 are performed again. The operation S309 is performed, to control the impedance adjustment circuit to adjust the impedance by local traversal. After the impedance is adjusted each time, the operation S308 is performed again. After determining that the impedance is mismatched, the operation S309 is performed; and after determining that the impedance is not mismatched, the operation S302 and operations after the operation S302 are performed again.

In some specific embodiments, after the adjustment solution is triggered, the adjustment solution may acquire the sampling signal at regular time, and determine whether the impedance adjustment circuit is turned on to adjust the impedance, according to the sampling signal. After one adjustment completes, the sampling signal is acquired at regular time again.

The disclosure further provides an electronic device, as shown in FIG. 1, the electronic device includes an amplifier 102, a sampling circuit 202, a processor circuit 210, an impedance adjustment circuit 206, and an antenna 212. The sampling circuit 202 and the impedance adjustment circuit 206 are sequentially connected in series between the amplifier 102 and the antenna 212, and the processor circuit 210 is coupled to the sampling circuit 202, the impedance adjustment circuit 206 and an aperture tuning circuit 208. The sampling circuit 202 is configured to acquire a signal from an output of the amplifier 102 and send the signal to the processor circuit 210. The processor circuit 210 is configured to load and execute a computer program, so that the electronic device performs the circuit adjustment method provided in the above embodiments.

The disclosure further provides a computer-readable storage medium, the computer-readable storage medium has stored thereon a computer program, and when the computer program is loaded and executed by the processor circuit, the circuit adjustment method provided in the above embodiments is implemented. The computer-readable storage medium may be a Ferromagnetic Random Access Memory (FRAM), a Read Only Memory (ROM), a Programmable Read-Only Memory (PROM), an Erasable Programmable Read-Only Memory (EPROM), an Electrically Erasable Programmable Read-Only Memory (EEPROM), a flash memory, a magnetic surface memory, an optical disk, or a Compact Disc Read-Only Memory (CD-ROM), or other memories.

The disclosure further provides a computer program product, the computer program product includes a computer program, and when the computer program is executed by a processor, the generation method provided in the above embodiments or the circuit adjustment method provided in the above embodiments is implemented.

In several embodiments provided in the disclosure, it should be understood that the disclosed devices and methods may be implemented in other manners. The device embodiments as described above are only schematic, and for example, division of the units is only a logic function division, and there may be other division manners in actual implementations. For example, multiple units or components may be combined or integrated into another system, or some features may be omitted or may not be executed. Furthermore, coupling or direct coupling or communication connection between displayed or discussed components may be indirect coupling or communication connection implemented through some interfaces, of the device or the units, and may be electrical, mechanical or use other forms.

The above units described as separate components may be or may not be physically separated, and components displayed as units may be or may not be physical units, that is, may be located in a place, or may be distributed to multiple network units. Part or all of the units may be selected to achieve the purpose of the solutions in the embodiments according to actual requirements.

Furthermore, each functional unit in the embodiments of the disclosure may be integrated into a processing unit, or each unit may be separately used as a unit, or two or more than two units may be integrated into a unit. The above integrated unit may be implemented in form of hardware or in form of hardware plus software functional units.

It may be understood that “one embodiment” or “an embodiment” mentioned throughout the description means that specific features, structures or characteristics related to the embodiment are included in at least one embodiment of the disclosure. Therefore, “in one embodiment” or “in an embodiment” present throughout the description does not necessarily refer to the same embodiment. Furthermore, these specific features, structures or characteristics may be combined in one or more embodiments in any suitable manner. It should be understood that in various embodiments of the disclosure, sizes of serial numbers of the above processes do not mean a sequence of execution, and the sequence of execution of each process should be determined by its function and internal logic, and should not constitute any limitation on implementation processes of the embodiments of the disclosure. The above serial numbers of the embodiments of the disclosure are only for the purpose of descriptions, and do not represent advantages and disadvantages of the embodiments.

It should be noted that terms “including”, “include” or any other variants thereof in the context are intended to encompass a non-exclusive inclusion, so that a process, method, article or apparatus including a series of elements includes not only those elements, but also other elements which are not explicitly listed, or elements inherent to such process, method, article or apparatus. Without further limitation, an element defined by a statement “including a . . . ” does not preclude presence of additional identical elements in a process, method, article or apparatus including the element.

The above descriptions are only implementations of the disclosure, however, the scope of protection of the disclosure is not limited thereto. Variation or replacement easily conceived by any technician familiar with this technical field within the technical scope disclosed in the disclosure, should fall within the scope of protection of the disclosure.

We claim:

1. A circuit adjustment method, comprising:
acquiring a sampling signal from an output of an amplifier, wherein the sampling signal comprises at least amplitude and/or phase information of a transmission signal and a reflection signal from the output of the amplifier;
determining whether impedance is mismatched according to the sampling signal;
adjusting the impedance by an impedance adjustment circuit connected to the output of the amplifier, if the impedance is mismatched.

2. The adjustment method of claim 1, wherein determining whether impedance is mismatched, according to the sampling signal comprises:
acquiring, according to the sampling signal, a first detection signal containing the amplitude information of the transmission signal and the reflection signal; and determining that the impedance is mismatched, when the first detection signal is less than or equal to a first preset threshold; and/or
acquiring, according to the sampling signal, a second detection signal containing a phase difference between the transmission signal and the reflection signal; and determining that the impedance is mismatched, when the second detection signal is greater than a second preset threshold.

3. The adjustment method of claim 2, further comprising:
acquiring the first detection signal, and comparing the first detection signal with the first preset threshold; and/or
acquiring the second detection signal, and comparing the second detection signal with the second preset threshold.

4. The adjustment method of claim 2, wherein adjusting the impedance by the impedance adjustment circuit connected to the output of the amplifier, if the impedance is mismatched, comprises:
controlling the impedance adjustment circuit to adjust the impedance according to the first detection signal and/or the second detection signal, if the impedance is mismatched.

5. The adjustment method of claim 4, wherein adjusting the impedance by the impedance adjustment circuit connected to the output of the amplifier, if the impedance is mismatched, comprises:
controlling the impedance adjustment circuit to adjust the impedance according to the first detection signal, if the impedance is mismatched; and
continuously controlling the impedance adjustment circuit to adjust the impedance according to the second detection signal.

6. The adjustment method of claim 1, further comprising before adjusting the impedance by the impedance adjustment circuit connected to the output of the amplifier:
resetting the impedance adjustment circuit; and
determining again whether the impedance is mismatched after the impedance adjustment circuit is reset.

7. The adjustment method of claim 1, wherein adjusting the impedance by the impedance adjustment circuit connected to the output of the amplifier comprises:
adjusting the impedance by looking up a table and/or by traversal.

8. The adjustment method of claim 7, wherein the sampling signal further comprises frequency information of the transmission signal and the reflection signal from the output of the amplifier,
adjusting the impedance by the impedance adjustment circuit connected to the output of the amplifier comprises:
looking up the table according to the amplitude and/or phase information of the transmission signal and the reflection signal in the sampling signal, in combination with the frequency information, and obtaining a table lookup result; and
controlling the impedance adjustment circuit to adjust the impedance, according to the table lookup result.

9. The adjustment method of claim 7, wherein adjusting the impedance by the impedance adjustment circuit connected to the output of the amplifier comprises:
controlling the impedance adjustment circuit to adjust the impedance, by looking up the table; and
adjusting the impedance by local traversal, if the impedance is still mismatched after the impedance is adjusted.

10. The adjustment method of claim 9, wherein the table comprises at least a primary table and a plurality of secondary tables, and the primary table corresponds to the plurality of secondary tables,
adjusting the impedance by the impedance adjustment circuit connected to the output of the amplifier comprises:
determining a table lookup result in the primary table, by looking up the table;
controlling the impedance adjustment circuit to adjust the impedance, according to the table lookup result; and
adjusting the impedance by traversing a secondary table corresponding to the table lookup result, if the impedance is still mismatched after the impedance is adjusted.

11. The adjustment method of claim 1, wherein acquiring the sampling signal from the output of the amplifier comprises:
acquiring the sampling signal from the output of the amplifier at a fixed time.

12. The adjustment method of claim 11, wherein a time interval for acquiring the sampling signal at the fixed time is 50 to 200 ms.
